(19) United States
(12) Patent Application Publication
(10) Pub. No.: US 2025/0329988 A1
(43) Pub. Date: Oct. 23, 2025

(54) ALIGNMENT OF A VOLUME BRAGG GRATING USING A LASER HEAD

(71) Applicant: Lumentum Operations LLC, San Jose, CA (US)

(72) Inventors: Li FAN, San Jose, CA (US); Qiaomei CHENG, San Jose, CA (US)

(21) Appl. No.: 18/900,037

(22) Filed: Sep. 27, 2024

Related U.S. Application Data
(60) Provisional application No. 63/636,325, filed on Apr. 19, 2024.

(51) Int. Cl. H01S 5/14; H01S 5/02251; H01S 5/02253; H01S 5/023

(52) U.S. Cl. CPC H01S 5/141; H01S 5/02251; H01S 5/02253; H01S 5/023

(57) ABSTRACT

In some implementations, a collimated beam may be provided at a volume Bragg grating (VBG) of a laser module. The collimated beam may comprise light generated by a laser chip of a laser head. A free lasing spectrum of the laser chip of the laser head may cover a reflection peak wavelength of the VBG. Scattered light may be received at a spectrum monitor. The scattered light may comprise scattered light from the collimated beam after passing through the VBG. An orientation of the VBG of the laser module may be adjusted based on a locked lasing spectrum of the scattered light such that the collimated beam is incident normal to a grating of the VBG.

### CROSS-REFERENCE TO RELATED APPLICATION

This Patent Application claims priority to U.S. Provisional Patent Application No. 63/636,325, filed on Apr. 19, 2024, and entitled “ALIGNMENT OF VOLUME BRAGG GRATING WITH A SINGLE-CHIP MODULE.” The disclosure of the prior Application is considered part of and is incorporated by reference into this Patent Application.

### TECHNICAL FIELD

The present disclosure relates generally to a volume Bragg grating (VBG) and to alignment of a VBG using a laser head.

### BACKGROUND

An optical Bragg grating is a transparent device with a periodic variation of refractive index such that a large reflectance may be reached in a wavelength range (e.g., a bandwidth) around a particular wavelength that fulfills the Bragg condition:

$$\frac{2 π}{Λ} = 2 \cdot \frac{2 π n}{λ} cos θ$$

where λ is the vacuum wavelength of light, n is the average refractive index of the medium, θ is the propagation angle in the medium relative to the direction normal to the grating, and ∧ is the grating period. If the Bragg condition is met, then the wavenumber of the grating matches the difference of the wavenumbers of the incident and reflected waves.

A volume Bragg grating (VBG) is a Bragg grating which is written inside a transparent material, for example, in the form of a cube or a parallelepiped (in contrast to diffraction gratings made on a surface of an optical element or a fiber Bragg grating, where the grating is written into a core of an optical fiber). Typically, a VBG is written into a photosensitive glass or in some cases a crystal material. A VBG typically has a sm

[symbol]

[symbol] all grating period (e.g., below 1 micrometer (μm)) so that reflection of light can be obtained in a narrow optical bandwidth—either directly back into an incoming beam or under some angle.

### SUMMARY

In some implementations, a method includes providing a collimated beam at a volume Bragg grating (VBG) of a laser module, the collimated beam comprising light generated by a laser chip of a laser head, wherein a free lasing spectrum of the laser chip of the laser head covers a reflection peak wavelength of the VBG; receiving scattered light at a spectrum monitor, the scattered light comprising scattered light from the collimated beam after passing through the VBG; and adjusting, based on a locked lasing spectrum of the scattered light, an orientation of the VBG of the laser module such that the collimated beam is incident normal to a grating of the VBG.

In some implementations, a method includes providing an output of a laser head as a collimated beam at a VBG of a laser module, the output of the laser head comprising light generated by a laser chip of the laser head, wherein a reflection peak wavelength of the VBG is within a free lasing spectrum of the laser chip; receiving scattered light at a spectrum monitor, the scattered light comprising scattered light from the collimated beam after passing through the VBG; and adjusting an orientation of the VBG of the laser module based on a locked lasing spectrum of the scattered light such that the collimated beam is incident normal to a grating of the VBG.

In some implementations, an alignment system includes a laser head comprising a fiber and a laser chip, wherein the fiber of the laser head is spliced to a fiber of a laser module comprising a VBG, and wherein a reflection peak wavelength of the VBG is within a free lasing spectrum of the laser chip; a spectrum monitor to monitor a locked lasing spectrum of scattered light, resulting from light generated by the laser chip, that passes through the VBG of the laser module; and an adjustment device to adjust an orientation of the VBG based on the locked lasing spectrum of the scattered light.

### BRIEF DESCRIPTION OF THE DRAWINGS

FIG. 1A is a diagram illustrating an example of a wavelength-locked laser module.

FIG. 1B is a diagram illustrating an example associated with alignment of a VBG using a backward launching technique with a fiber-coupled tunable laser.

FIGS. 2A-2B are diagrams illustrating examples associated with alignment of a VBG using a laser head.

FIG. 3 illustrates example experimental results of wavelength locking of a laser head at different temperatures.

FIG. 4 is a flowchart of an example process associated with alignment of a VBG using a laser head.

### DETAILED DESCRIPTION

The following detailed description of example implementations refers to the accompanying drawings. The same reference numbers in different drawings may identify the same or similar elements.

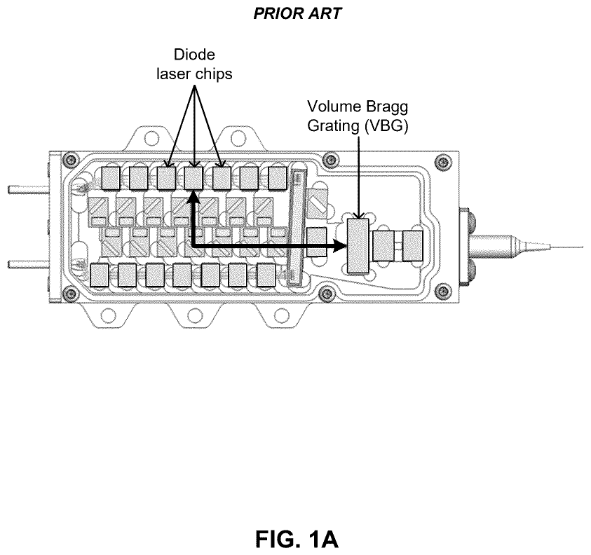

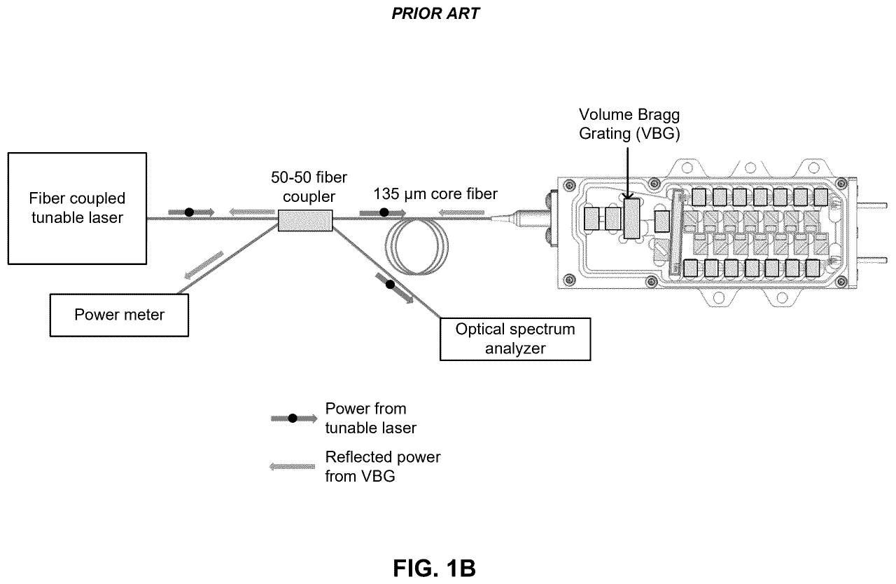

A VBG can be used for wavelength locking a laser module based on laser injection. Typically, a VBG is manufactured by exposing a photo-thermo-refractive (PTR) glass to an interference pattern from an ultraviolet laser. To achieve injection wavelength locking, a collimated laser beam must be perpendicular to a grating of the VBG (rather than perpendicular to a glass surface of the VBG). FIG. 1A is a diagram illustrating an example of a wavelength-locked laser module. In a wavelength-locked laser module such as that shown in FIG. 1A, a beam from a given diode laser chip is collimated by a fast-axis collimating (FAC) and slow-axis collimating (SAC) lens, and the collimated beam is adjusted by a folding mirror such that the collimated beam is perpendicular to the grating of the VBG. Reflected laser photons selected by a reflection peak wavelength of the VBG follow their incoming path and go back to a cavity of the diode laser chip. This process is referred to as injection lasing wavelength locking in the diode laser chip. Notably, an orientation of the VBG is critical to the performance of the wavelength-locked laser module. If the orientation of the VBG is non-ideal, then fiber coupling efficiency and wavelength locking range are compromised.

One technique for VBG alignment uses a forward launching technique. According to this technique, the VBG of the laser module is aligned such that a particular laser chip of the laser module is locked. After alignment of the VBG, the VBG is epoxied such that the position and orientation of the VBG are fixed. Next, channels corresponding to other laser chips of the laser module are aligned such that the wavelength of each channel is locked. However, if the alignment of the particular laser chip is compromised, then the alignments of the other channels in the laser module may be difficult or impossible to correct (since alignment of each other channel depends on the alignment of the first channel).

Another technique for VBG alignment uses a backward launching technique with a narrow linewidth fiber-coupled tunable laser. FIG. 1B is a diagram illustrating an example associated with alignment of a VBG using a backward launching technique with a fiber-coupled tunable laser. According to this technique, a lasing wavelength of the fiber-coupled tunable laser is tuned to the reflection peak wavelength of the VBG (based on monitoring performed by an optical spectrum analyzer). An alignment station then adjusts the orientation of the VBG such that the highest reflected power, as monitored by a power meter, is observed. However, the tunable laser used for such alignment is expensive and in some cases may not be reliable, which can result in significant downtime with respect to performance of the VBG alignment process.

Some implementations described herein enable alignment of a VBG using a laser head (e.g., a single-chip laser module). In some implementations, a collimated beam is provided at a VBG of a laser module, with the collimated beam comprising light generated by a laser chip of a laser head, and a free lasing spectrum of the laser chip of the laser head covers a reflection peak wavelength of the VBG. Scattered light is then received at a spectrum monitor, with the scattered light comprising scattered light from the collimated beam after passing through the VBG. An orientation of the VBG of the laser module is then adjusted based on a locked lasing spectrum of the scattered light such that the collimated beam is incident normal to a grating of the VBG.

In some implementations, the techniques and apparatuses described herein enable alignment of a VBG in a wavelength-locked laser module using a laser head (e.g., a single-chip laser module). In some implementations, the techniques and apparatuses described herein provide improved reliability of achieving alignment of channels of the laser module by eliminating reliance on a single channel of the laser module to provide VBG alignment (as in the forward launching technique described above). Further, the laser head used in association with the techniques and apparatuses described herein is of a relatively low-cost and more readily manufacturable (e.g., as compared to a fiber-coupled tunable laser needed for the backward launching technique with a narrow linewidth fiber-coupled tunable laser described above). As a result, the techniques and apparatuses described herein reduce cost and improve reliability of a VBG alignment procedure.

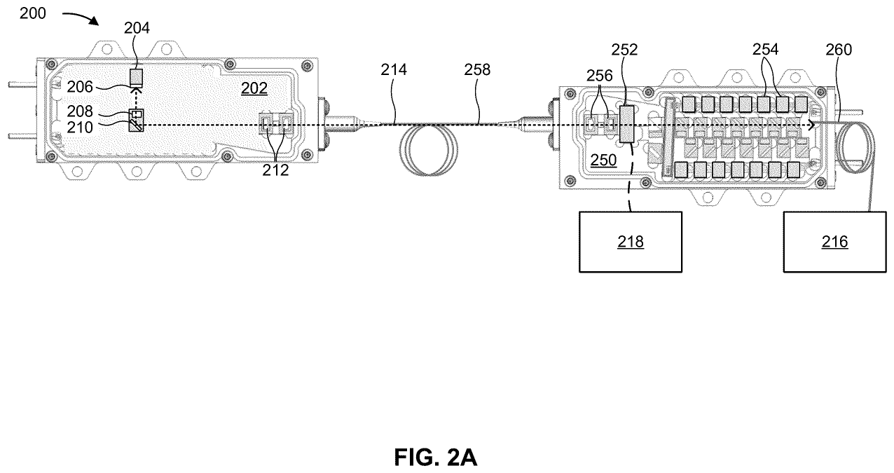

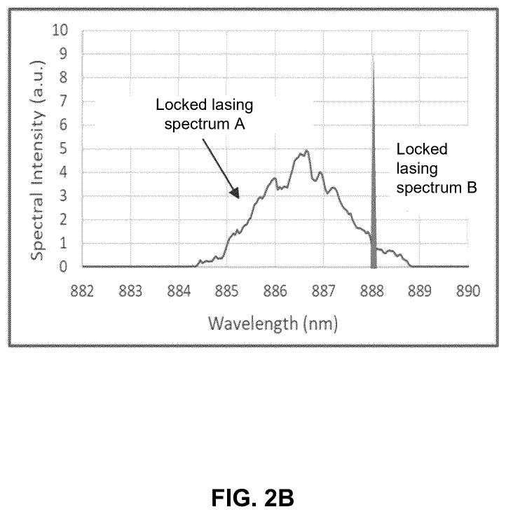

FIGS. 2A-2B are diagrams illustrating an example alignment system 200 associated with alignment of a VBG of a laser module using a laser head. In FIG. 2A, the alignment system 200 includes a laser head 202 including a laser chip 204. The laser head 202 includes a first set of lenses 206, a second set of lenses 208, a reflective element 210, a third set of lenses 212, and a fiber 214. The alignment system 200 further includes a spectrum monitor 216 and an adjustment device 218. In the example shown in FIG. 2A, the alignment system 200 can be used to align a VBG 252 of a laser module 250. As shown, the laser module 250 includes the VBG 252, a plurality of laser chips 254 (e.g., a plurality of laser chips having a chip-on submount (COS) architecture), a set of lenses 256, and a fiber 258. As shown, a fiber 260 may be arranged so as to receive scattered light from the laser module 250 and provide the scattered light to the spectrum monitor 216. As further shown, the fiber 214 of the laser head 202 may be spliced to the fiber 258 of the laser module 250. In some implementations, the fiber 214 and the fiber 258 may have one or more matching characteristics (e.g., the fiber 214 and the fiber 258 may each comprise a 135 micrometer (μm) core and a 0.22 numerical aperture (NA)).

The laser head 202 is a component to provide a collimated beam at the VBG 252 of the laser module 250 in association with enabling alignment of the VBG 252. In some implementations, the laser head 202 is a single-chip laser module. That is, in some implementations, the laser head 202 includes only one laser chip 204 (rather than multiple laser chips, as in the case of the laser module 250). In some implementations, the use of a single-chip laser module for the laser head 202 reduces cost and complexity of the laser head 202. In some implementations, the laser chip 204 has a COS architecture. In some implementations, the laser head 202 is configured to operate in a continuous wave (CW) mode (e.g., such that the laser head 202 outputs a continuous beam of light over a given period of time).

The laser chip 204 comprises a laser diode to generate light. In some implementations, a free lasing spectrum of the laser chip 204 of the laser head 202 covers a reflection peak wavelength of the VBG 252. That is, in some implementations, the reflection peak wavelength of the VBG 252 is within the free lasing spectrum of the laser chip 204. In some implementations, the free lasing spectrum of the laser chip 204 of the laser head 202 covering the reflection peak wavelength of the VBG 252 enables alignment of the VBG 252, as described below. In some implementations, the reflection peak wavelength of the VBG 252 is in a range from approximately 887.5 nanometers (nm) to approximately 887.9 nm, such as 887.7 nm. Thus, in some implementations, the free lasing spectrum of the laser chip 204 covers a range from approximately 887.5 nm to approximately 887.9 nm.

The first set of lenses 206 comprises one or more lenses to collimate the light generated by the laser chip 204. In some implementations, the first set of lenses 206 may include a fast-axis collimating (FAC) lens (e.g., a lens configured to collimate light in the fast-axis direction). The second set of lenses 208 comprises one or more lenses to further collimate the light generated by the laser chip (after collimation by the first set of lenses 206). In some implementations, the second set of lenses 208 may include a slow-axis collimating (SAC) lens (e.g., a lens configured to collimate light in the slow-axis direction). The reflective element 210 comprises one or more elements (e.g., a mirror) to reflect or otherwise direct a collimated beam of light (e.g., after collimation of the light by the first set of lenses 206 and the second set of lenses 208). In some implementations, the reflective element 210 and the second set of lenses 208 may be used in association with coupling the light to the fiber 214 of the laser head 202 after collimation by the first set of lenses 206. In some implementations, the third set of lenses 212 may focus the collimated beam of light such that the beam is provided to the fiber 214.

The spectrum monitor 216 includes one or more components to monitor a locked lasing spectrum of scattered light, resulting from light generated by the laser chip 204, that passes through the VBG 252 of the laser module 250. For example, the spectrum monitor 216 may in some implementations include an optical spectrum analyzer (OSA) that can be used to monitor a locked lasing spectrum of scattered light that is provided to the spectrum monitor 216 (via the fiber 260). In some implementations, an orientation of the VBG 252 can be adjusted based at least in part on the monitoring of the locked lasing spectrum of the scattered light, as described below.

The adjustment device 218 includes one or more components to adjust an orientation of the VBG 252 based on the locked lasing spectrum of the scattered light. For example, the adjustment device 218 may include one or more components that can move, rotate, or otherwise modify a position of the VBG 252. In some implementations, the orientation of the VBG 252 is adjusted based on the locked lasing spectrum of the scattered light such that the collimated beam provided at the VBG 252 is incident normal to a grating of the VBG 252, as described below.

In an example operation of the alignment system 200, the laser chip 204 of the laser head 202 generates light. The light generated by the laser chip 204 is collimated (e.g., along the fast-axis) by the first set of lenses 206 of the laser head 202. The light collimated by the first set of lenses 206 is then collimated (e.g., along the slow-axis) by the second set of lenses 208. A resulting collimated beam is then directed by the reflective element 210 such that the collimated beam is provided to the third set of lenses 212, and the light is focused by the third set of lenses 21 such that the light is coupled into the fiber 214. Here, the fiber 214 of the laser head 202 is spliced to the fiber 258 of the laser module 250. Light from the fiber 258 is provided to the set of lenses 256 such that a collimated beam is incident on the VBG 252 of the laser module 250. Here, a first portion of the optical power (e.g., 10%) of the collimated beam at the VBG 252 is reflected back on the optical path to the laser chip 204 (such that the lasing spectrum of the laser chip 204 is locked), while a second portion of the optical power (e.g., 90%) of the collimated beam at the VBG 252 passes through the VBG 252. The light that passes through the VBG 252 is scattered in the laser module 250, and some portion of the scattered light reaches an input of the fiber 260. The fiber 260 provides the scattered light received at the input of the fiber 260 to the spectrum monitor 216.

The spectrum monitor 216 can then be used to monitor a locked lasing spectrum of the scattered light. As noted above, the reflection of the first portion of the collimated beam back to the laser chip 204 provides wavelength locking of the laser chip 204. Thus, the locked lasing spectrum monitored by the spectrum monitor 216 is the locked lasing wavelength of the laser chip 204. The adjustment device 218 can then be used to adjust an orientation of the VBG 252 based on the locked lasing spectrum of the scattered light. For example, if the orientation of the VBG 252 is non-ideal, then the locked lasing spectrum as monitored by the spectrum monitor 216 may be relatively wide, an example of which is illustrated by locked lasing spectrum A in FIG. 2B. Conversely, if the orientation of the VBG 252 is ideal or near-ideal, then the locked lasing spectrum as monitored by the spectrum monitor 216 may be relatively narrow (e.g., centered at or near the reflection peak wavelength of the VBG 252), an example of which is illustrated by locked lasing spectrum B in FIG. 2B. Thus, the locked lasing spectrum is indicative of whether the VBG orientation is ideal or near-ideal. In practice, the adjustment device 218 may adjust the orientation of the VBG 252 until the locked lasing spectrum as monitored by the spectrum monitor 216 is relatively narrow and centered at or near the reflection peak wavelength of the VBG 252 (e.g., 887.7 nm in the example shown in FIG. 2B). Notably, the locked lasing spectrum being relatively narrow and centered at or near the reflection peak wavelength of the VBG 252 means that the collimated beam is incident normal to a grating of the VBG 252. Thus, the adjustment device 218 adjusts the orientation of the VBG 252 based on the locked lasing spectrum such that the collimated beam is incident normal to the grating of the VBG 252. In this way, the VBG 252 can be aligned using the laser head 202. In some implementations, the laser head 202 is configured to operate in a CW mode and at a particular temperature and current during alignment of the VBG 252. Notably, while the examples described herein demonstrate wavelength locking in an 888-nm wavelength locked module, the techniques and apparatuses described herein can be readily applied to any other diode laser wavelength.

As indicated above, FIGS. 2A-2B are provided as examples. Other examples may differ from what is described with regard to FIGS. 2A-2B. Further, the number and arrangement of components and/or elements shown in FIG. 2A are provided as an example. In practice, there may be additional components and/or elements, fewer components and/or elements, different components and/or elements, or differently arranged components and/or elements than those shown in FIG. 2A.

In some implementations, because the optical power reflected from the VBG 252 back to the laser chip is low (e.g., 10% or less), a locking range may be limited, meaning that accurate alignment of the VBG 252 may be difficult or impossible to achieve. To address this concern, the free lasing wavelength of the laser chip 204 (e.g., at a given current and temperature) may be configured such that the free lasing spectrum covers (e.g., includes or overlaps) the reflection peak wavelength of the VBG 252. Therefore, in some implementations, the free lasing spectrum of the laser chip 204 covers the reflection peak wavelength of the VBG 252.

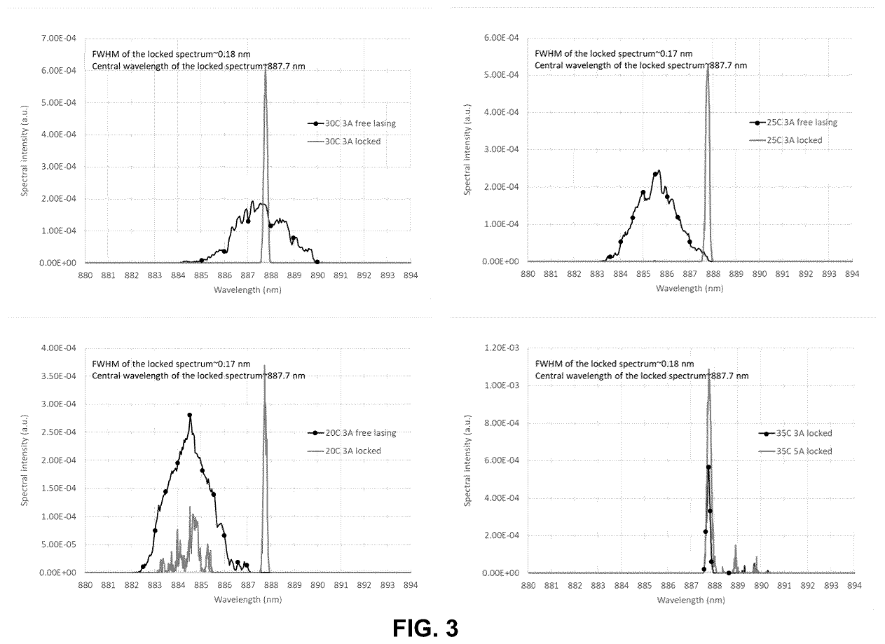

FIG. 3 illustrates example experimental results of wavelength locking of the laser head 202 at different temperatures. In the examples shown in FIG. 3, the laser head 202 operates at a current of 3 amperes (A). Lines labeled “free lasing” represent free lasing spectrums of the laser chip 204 at various temperatures (e.g., 30 degrees Celsius (° C.) in the upper left diagram, 25° C. in the upper right diagram, 20° C. in the lower left diagram, and 35° C. in the lower right diagram) as monitored by a spectrum monitor prior to a VBG 252 being mounted in a laser module 250.

Lines labeled “locked” represent locked lasing spectrums of the laser chip 204 at the various temperatures as monitored by the spectrum monitor 216 after the VBG 252 is mounted in the laser module 250 and alignment of the VBG 252 is attempted. In these examples, the reflection peak wavelength of the VBG 252 is 887.7 nm.

As shown in the upper left diagram of FIG. 3, at 3 A and 30° C., the free lasing spectrum of the laser chip 204 covers the reflection peak wavelength of the VBG 252. Here, as indicated by the singular narrow peak of the locked lasing spectrum, the lasing spectrum of the laser chip 204 can be locked in a narrow range, which enables accurate alignment of the VBG 252.

Similarly, as shown in the upper right diagram of FIG. 3, at 3 A and 25° C., the free lasing spectrum of the laser chip 204 covers the reflection peak wavelength of the VBG 252 (even though the reflection peak wavelength is near an upper limit of the free lasing spectrum). Here, as indicated by the singular narrow peak of the locked lasing spectrum, the lasing spectrum of the laser chip 204 can be locked in a narrow range, which enables accurate alignment of the VBG 252.

However, as shown in the lower left diagram of FIG. 3, at 3 A and 20° C., the free lasing spectrum of the laser chip 204 does not cover the reflection peak wavelength of the VBG 252. Here, as indicated by the irregular and inconsistent nature of the locked lasing spectrum, the lasing spectrum of the laser chip 204 cannot be locked in a narrow range, which precludes accurate alignment of the VBG 252.

Similarly, as shown in the lower left diagram of FIG. 3, at 3 A and 35° C., the free lasing spectrum of the laser chip 204 is relatively small and does not cover the reflection peak wavelength of the VBG 252. Here, as indicated by the irregular and inconsistent nature of the locked lasing spectrum, the lasing spectrum of the laser chip 204 cannot be locked in a narrow range, which is prohibitive of accurate alignment of the VBG 252.

As indicated above, FIG. 3 is provided as an example. Other examples may differ from what is described with regard to FIGS. 3.

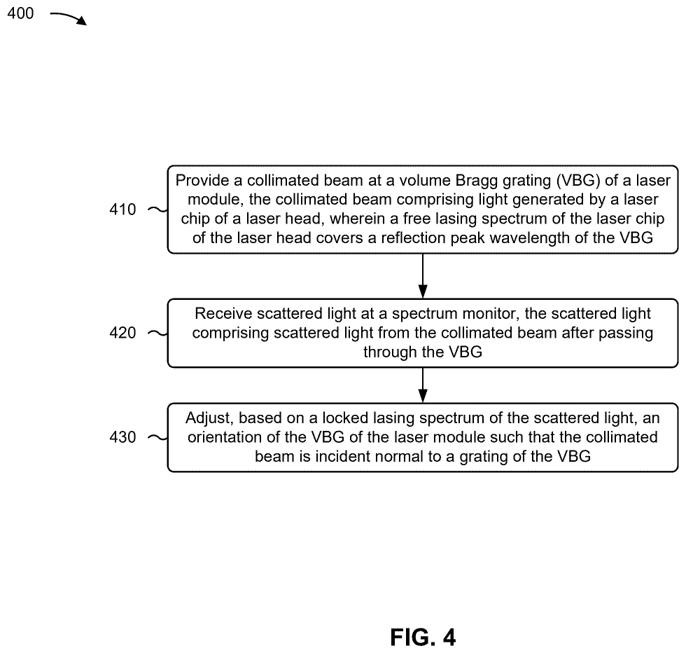

FIG. 4 is a flowchart of an example process 400 associated with alignment of a VBG using a laser head. In some implementations, one or more process blocks of FIG. 4 are performed by a laser head (e.g., laser head 202), a spectrum monitor (e.g., spectrum monitor 216), and/or an adjustment device (e.g., adjustment device 218).

As shown in FIG. 4, process 400 may include providing a collimated beam at a VBG of a laser module, the collimated beam comprising light generated by a laser chip of a laser head, wherein a free lasing spectrum of the laser chip of the laser head covers a reflection peak wavelength of the VBG (block 410). For example, the laser head may provide a collimated beam at a VBG of a laser module (e.g., VBG 252 of the laser module 250), the collimated beam comprising light generated by a laser chip (e.g., laser chip 204) of the laser head, wherein a free lasing spectrum of the laser chip of the laser head covers a reflection peak wavelength of the VBG, as described above. Put another way, in some implementations, an output of the laser head is provided as a collimated beam at the VBG of the laser module, with the output of the laser head comprising light generated by the laser chip of the laser head, and with a reflection peak wavelength of the VBG being within a free lasing spectrum of the laser chip.

As further shown in FIG. 4, process 400 may include receiving scattered light at a spectrum monitor, the scattered light comprising scattered light from the collimated beam after passing through the VBG (block 420). For example, the scattered light may be received at the spectrum monitor, with the scattered light comprising scattered light from the collimated beam after passing through the VBG, as described above.

As further shown in FIG. 4, process 400 may include adjusting, based on a locked lasing spectrum of the scattered light, an orientation of the VBG of the laser module such that the collimated beam is incident normal to a grating of the VBG (block 430). For example, the adjustment device may adjust, based on a locked lasing spectrum of the scattered light, an orientation of the VBG of the laser module such that the collimated beam is incident normal to a grating of the VBG, as described above.

Process 400 may include additional implementations, such as any single implementation or any combination of implementations described below and/or in connection with one or more other processes described elsewhere herein.

In a first implementation, the collimated beam is provided at the VBG via a fiber (e.g., fiber 214) of the laser head and a fiber (e.g., fiber 258) of the laser module, the fiber of the laser head being spliced to the fiber of the laser module.

In a second implementation, alone or in combination with the first implementation, the light generated by the laser chip is collimated by a first set of lenses (e.g., first set of lenses 206) and the collimated light is coupled into a fiber of the laser head by a reflective element (e.g., reflective element 210) and a second set of lenses (e.g., second set of lenses 208).

In a third implementation, alone or in combination with one or more of the first and second implementations, the laser head is a single-chip laser module.

In a fourth implementation, alone or in combination with one or more of the first through third implementations, the laser chip has a COS architecture.

In a fifth implementation, alone or in combination with one or more of the first through fourth implementations, the laser module comprises a plurality of laser chips, each having a COS.

In a sixth implementation, alone or in combination with one or more of the first through fifth implementations, the laser head operates in a continuous wave mode.

In a seventh implementation, alone or in combination with one or more of the first through sixth implementations, the laser head operates at a fixed temperature and a fixed current during the adjustment of the orientation of the VBG.

In an eighth implementation, alone or in combination with one or more of the first through seventh implementations, the reflection peak wavelength of the VBG is in a range from approximately 887.5 nm to approximately 887.9 nm.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A method, comprising:
providing a collimated beam at a volume Bragg grating (VBG) of a laser module, the collimated beam comprising light generated by a laser chip of a laser head,
wherein a free lasing spectrum of the laser chip of the laser head covers a reflection peak wavelength of the VBG;
receiving scattered light at a spectrum monitor, the scattered light comprising scattered light from the collimated beam after passing through the VBG; and
adjusting, based on a locked lasing spectrum of the scattered light, an orientation of the VBG of the laser module such that the collimated beam is incident normal to a grating of the VBG.

2. The method of claim 1, wherein the collimated beam is provided at the VBG via a fiber of the laser head and a fiber of the laser module, the fiber of the laser head being spliced to the fiber of the laser module.

3. The method of claim 1, wherein the light generated by the laser chip is collimated by a first set of lenses and the collimated light is coupled into a fiber of the laser head by a reflective element and a second set of lenses.

4. The method of claim 1, wherein the laser head is a single-chip laser module.

5. The method of claim 1, wherein the laser chip has a chip-on-submount (COS) architecture.

6. The method of claim 1, wherein the laser module comprises a plurality of laser chips, each having a chip-on-submount (COS).

7. The method of claim 1, wherein the laser head operates in a continuous wave mode.

8. The method of claim 1, wherein the laser head operates at a fixed temperature and a fixed current during the adjustment of the orientation of the VBG.

9. The method of claim 1, wherein the reflection peak wavelength of the VBG is in a range from approximately 887.5 nanometers (nm) to approximately 887.9 nm (e.g., 887.7 nm)

10. A method, comprising,
providing an output of a laser head as a collimated beam at a volume Bragg grating (VBG) of a laser module, the output of the laser head comprising light generated by a laser chip of the laser head,
wherein a reflection peak wavelength of the VBG is within a free lasing spectrum of the laser chip;
receiving scattered light at a spectrum monitor, the scattered light comprising scattered light from the collimated beam after passing through the VBG; and
adjusting an orientation of the VBG of the laser module based on a locked lasing spectrum of the scattered light such that the collimated beam is incident normal to a grating of the VBG.

11. The method of claim 10, wherein the collimated beam is provided at the VBG via a fiber of the laser head and a fiber of the laser module, the fiber of the laser head being spliced to the fiber of the laser module.

12. The method of claim 10, wherein the light generated by the laser chip is collimated by a first set of lenses and the collimated light is coupled into a fiber of the laser head by a reflective element and a second set of lenses.

13. The method of claim 10, wherein the laser head is a single-chip laser module.

14. The method of claim 10, wherein the laser chip has a chip-on-submount (COS) architecture.

15. The method of claim 10, wherein the laser module comprises a plurality of laser chips, each having a chip-on-submount (COS).

16. The method of claim 10, wherein the reflection peak wavelength of the VBG is in a range from approximately 887.5 nanometers (nm) to approximately 887.9 nm (e.g., 887.7 nm)

17. An alignment system, comprising:
a laser head comprising a fiber and a laser chip,
wherein the fiber of the laser head is spliced to a fiber of a laser module comprising a volume Bragg grating (VBG), and
wherein a reflection peak wavelength of the VBG is within a free lasing spectrum of the laser chip;
a spectrum monitor to monitor a locked lasing spectrum of scattered light, resulting from light generated by the laser chip, that passes through the VBG of the laser module; and
an adjustment device to adjust an orientation of the VBG based on the locked lasing spectrum of the scattered light.

18. The alignment system of claim 17, wherein the laser head further comprises:
a first set of lenses to collimate the light generated by the laser chip; and
a reflective element and a second set of lenses to couple the light to a fiber of the laser head after collimation by the first set of lenses.

19. The alignment system of claim 17, wherein the laser head is a single-chip laser module.

20. The alignment system of claim 17, wherein the laser chip has a chip-on-submount (COS) architecture.
